(19) United States
(12) Patent Application Publication
(10) Pub. No.: US 2014/0236511 A1
(43) Pub. Date: Aug. 21, 2014

(54) SYSTEM AND METHOD FOR DETERMINING STATE OF CHARGE OF A BATTERY

(71) Applicant: KPIT Cummins Infosystems Ltd., Pune (IN)

(72) Inventors: Prakash Aravind Rao Kulkarni, Bangalore (IN); Muralidhara JP, Bangalore (IN); Mitesh Shah, Banswara (IN)

(73) Assignee: KPIT Cummins Infosystems Ltd., Pune (IN)

(21) Appl. No.: 14/348,546

(22) PCT Filed: Sep. 18, 2012
(86) PCT No.: PCT/IN2012/000627

§ 371 Date: Mar. 28, 2014

(30) Foreign Application Priority Data
Sep. 30, 2011 (IN) 2780/MUM/2011

(51) Int. Cl. G01R 31/36

(52) U.S. Cl. CPC G01R 31/3606
USPC 702/63

(57) ABSTRACT

A novel method and system for determining state of charge of a battery (SOC) is disclosed wherein the direct method and the indirect method are not used at the same time, but alternately as indicated by battery current status. The method of the invention compensates for the exiting modeling errors and parameter estimation errors to provide an accurate SOC estimation. The method of the invention computes the DC offset and the battery capacitance to compensate for the exiting modeling errors and parameter estimation errors.

### FIELD OF INVENTION

The present invention generally relates to a method and system to determine the state of charge of a battery. The present invention more specifically relates to a method and system to determine the state of charge (SOC) for Lithium based batteries.

### BACKGROUND OF INVENTION

State of Charge (SOC) of a battery is the equivalent of a fuel gauge for a battery or a battery pack and provides the battery capacity. In other words, SOC is the ratio of charge stored in the battery to the maximum charge that the battery can hold. SOC is also expressed in percentage. The battery is usually not charged above 90% and below 20% SOC.

Determining the battery SOC is quite crucial for various applications. The battery SOC, when estimated, provides an indication of remnant charge in the battery and how long it can be used for a particular application.

Various methods have been proposed for estimating the battery SOC. The existing methods do not provide an accurate SOC estimation as they are dependent on parameters of the battery which change with age, usage, etc. Further, the constants and errors in the equations used for SOC estimation are not accounted and compensated for leading to an inaccurate SOC estimation.

The typical approach of most of the existing methods is to identify the best battery model and then to estimate the model parameters as accurately as possible. These existing methods, like Kalman filter method and similar other methods are quite complex in nature. They require floating point arithmetic and therefore are not suitable for low power and low cost fixed point micro controllers.

Typically SOC is estimated using two methods:
1. Direct method i.e. Coulomb counting
2. Indirect method i.e. using battery characteristics i.e. SOC v/s OCV and battery circuit model

There are three well-known approaches for estimation of SOC.

Approach 1: Use of only direct method whenever battery is operating. This approach requires initial value of SOC which is to be obtained from SOC v/s OCV characteristics, when open circuited voltage is measured after resting the battery.

Approach 2: Use of only indirect method which involves estimating battery parameters of a complex battery dynamic circuit model.

Approach 3: Use of direct and indirect methods simultaneously which form state equations of Kalman or extended Kalman Filters.

Approach 1 suffers divergence of estimation error due to accumulation of DC current offsets and also due to battery capacity degradations.

Approach 2 makes assumption that battery can be represented by a linear circuit model with slow varying battery parameters which is not the case. Due to such assumption, estimation of parameters suffers inaccuracy especially during high battery current and also near constant battery current.

Approach 3 is derived from linear systems theory which tends to be unstable and divergent due to impairments such as non-simultaneous sampling of battery voltage and current, DC offsets and colored noise etc.

Additionally, the existing SOC equations do not compensate for the DC offset and the battery capacitance leading to an inaccurate SOC estimation. Most of the existing SOC equations cannot be used for a longer period of time due to the presence DC offset and decay of battery capacitance over a period of time. The effect of unknown DC offset or unknown battery capacitance is that the SOC estimation diverges with the progress of time. This requires that the SOC estimation is reinitialized whenever the current is lowered and the battery is relaxed.

The following table elaborates the merits and demerits of direct and indirect methods:

| | Merits | Demerits |
|---|---|---|
| Direct | Only current measurement is | Very accurate knowledge of initial |
| Method | necessary: voltage and temperature | SOC and battery capacity is |
| | measurements are not needed. | needed which is a difficult |
| | If the initial SOC and actual battery | requirement. |
| | capacity is accurately known then | For any practical sensor it is not |
| | estimation of SOC is very accurate | possible to avoid DC offset, noise, |
| | compared to Indirect Method at least | errors due to ADC quantization or |
| | on a short term basis. | errors due to gain variations in |
| | Very simple to implement and no | analog signal processing chain due |
| | complex modeling is required as in | to ambient conditions and aging. |
| | Indirect Method. | Due to these limitations in current |
| | | measurement, SOC estimation |
| | | error has a tendency to diverge in the |
| | | long run (note that SOC is |
| | | computed as an integral or |
| | | summation). |
| Indirect | SOC estimation using this method does | The impedance Z is not a constant |
| Method | not diverge as in the direct method. | parameter. It is highly nonlinear |
| | The range of accuracy/error can be | and varies with respect to time as it |
| | known in advance. | depends on various other factors |
| | Tolerant to the measurement | such as current, SOC, aging, |
| | inaccuracies or limitations compared to | temperature and current polarity. |
| | Direct Method | Therefore this parameter has to be |
| | | updated frequently by online |
| | | system identification techniques. |
| | | Since it is AC impendence, |
| | | effectiveness of its estimation |
| | | depends on a load profile. For |
| | | example during charging when the |
| | | current is more or less constant it |
| | | is almost impossible to estimate Z. |
| | | Voltmeter and temperature sensors |
| | | are required to estimate Z in |
| | | addition to the current sensor. |
| | | Any battery circuit model is only |
| | | an approximation and accurate |
| | | only to a certain extent. SOC |
| | | estimation errors are not only due |
| | | to measurement inaccuracies but |
| | | also due to modeling inaccuracies. |

Thus, there is a need for a method for battery SOC estimation which provides an accurate SOC estimation by taking into consideration the DC offset and the battery capacitance. There is a need for method for battery SOC estimation that minimizes the requirement of division operation and at the same time accomplishes performance comparable to the existing complex algorithms.

### SUMMARY

The present invention discloses a method and system to minimize DC offset current and battery capacitance errors thereby compensating for modeling errors and parameter estimation errors during determination of accurate State of Charge (SOC) of a battery, comprising a direct method and an indirect method, wherein said direct method and an indirect method are not used simultaneously, are used alternatively or conditionally depending on battery current status; after initiation of the system, determination of State of Health (SOH) of the battery and determination of battery capacity using least square method.

Additionally, the present invention discloses a method for battery SOC estimation which is simple in nature and which minimizes the requirement of division operation and at the same time accomplishes performance comparable to the existing complex algorithms.

### BRIEF DESCRIPTION OF DRAWINGS

FIG. 1 illustrates flowchart of State of Charge estimation (SOC) estimation.

FIG. 2 illustrates typical relation between Open Circuit Voltage (OCV) and State of Charge (SOC).

FIG. 3 illustrates resistive representation of OCV of a battery.

FIG. 4 illustrates the battery current status, directed to the use of direct and indirect method.

FIG. 5 illustrates the flowchart of State of Health (SOH) estimation

### DEFINITIONS

1) State of charge (SOC) of a battery is the ratio of charge stored in the battery to the maximum charge that the battery can hold. SOC is often expressed in percentage.
2) State of Health (SOH) of a battery is the ratio of actual battery capacity to the rated or fresh battery capacity. It is also a figure of merit of the condition of a battery compared to its ideal condition. SOH is often expressed in percentage.
3) OCV denotes open circuit voltage. It is the potential difference between two terminals of a device when there is no external load connected i.e. open circuit.
4) ‘T’ denote sampling period. It is the time between samples.
5) ‘I’ is the measured current, expressed in amperes.
6) ‘d’ is the offset current, expressed in amperes.
7) ‘C’ denotes battery capacity, expressed in coulombs. It is the amount of electric charge it can store.
8) R denotes resistance, expressed in ohms.

### DETAILED DESCRIPTION

The system and method of the invention provides for accurate estimation of Lithium based batteries irrespective of the existing modeling errors and parameter estimation errors is disclosed. In the view of drawbacks, the approach followed in this disclosure is nonlinear which differs from the existing approaches which are essentially linear. The approach in the present invention is not only simple but is also robust as it tolerates the impairments mentioned above. The State of Charge (SOC) is estimated using both direct and indirect methods but not simultaneously. The method of the present invention switches between either direct or indirect method in order to minimize error in estimation after identifying the conditions where one method is better than the other. Thus at a given time, SOC is computed by only one method.

The direct and indirect methods are reviewed below.

Direct Method:

By definition, SOC is the ratio of charge remaining in the battery to the capacity of the battery. Standard practice is to express SOC in percentage. SOC of a battery increases by charging and decreases by discharging.

The relation between SOC and battery current (charging or discharging) is depicted in the following equation.

$$SOC ( t 2 ) = SOC ( t 1 ) + \frac{1}{C} {\int }_{t 1}^{t 2} ( i ( t ) - d ) d t \qquad Eq . 1$$

Where
SOC(t2) is SOC of battery at time t2,
SOC(t1) is SOC of battery at time t1 and where t2>t1,
i(t) is the measured battery current in amperes
C is the battery capacity expressed in Coulombs.
d—Is current offset

For computer programs, the following discretized version of the above Eq. 1 is more appropriate.

$$SOC ( n ) = SOC ( n - 1 ) + \frac{( i [ n ] - d ) Δ T}{C} \qquad Eq . 2$$

Where
SOC(n) is the SOC at n^{th} sample time,
SOC(n−1) is the SOC at (n−1)^{th} sample time,
ΔT is the sampling period (typically 1 second),
I[n] is the battery current.
C is battery capacity (expressed in Coulombs)
d is current offset

Using Eq. 2, estimation of SOC at any sample time n is possible with knowledge of SOC at n−1. Further, the battery current measurement is sampled at ΔT between n−1 and n samples and the exact battery capacity and DC offset of current measurement should be known.

Indirect Method:

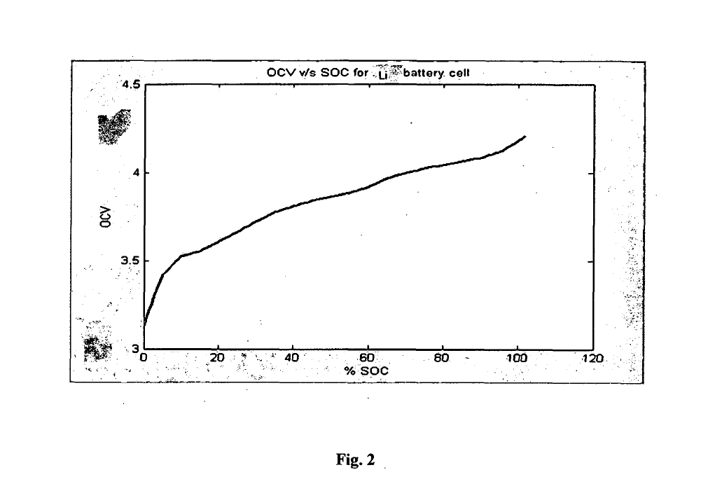

It is a well-established empirical fact that OCV of a Li-Ion battery depends only on SOC of the battery and not on any other factors such as temperature, battery capacity or history of battery loading or charging profiles. The relationship between OCV and SOC is usually non-linear which is depicted in FIG. 2. The battery SOC can be found out by referring to the battery characteristics or OCV v/s SOC look up table with interpolation, once. OCV of the battery is known.

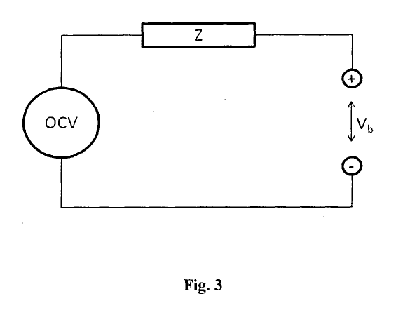

However, estimating OCV when battery is either loaded, or under charging condition or when it is not yet sufficiently relaxed to a stable open circuit voltage is rather a difficult task. Battery circuit models of varying complexities are used with the help of other measurable quantities to find OCV, such as terminal voltage and battery current. As illustrated in FIG. 3, a simple lumped battery model that consists of a non-constant voltage source in series with impedance Z is considered. Typically Z is AC impedance i.e. capacitive, indicating that the model is dynamic instead of static and the circuit equation is either a differential equation in time domain or Laplace Transform equation in Laplace domain. According to the following equation,

OCV(s)=V_{b}(s)−I_{b}(s)Z(s) Eq. 3,

the knowledge of battery terminal voltage V_{b} and battery current I_{b} together with the knowledge of AC impedance Z is sufficient to find OCV. Once OCV is determined it is possible to estimate the corresponding SOC from the relation shown in FIG. 2.

The present invention disclosed herein employs both direct and indirect methods in at appropriate conditions one at a time, while overcoming respective drawbacks of both the methods. Further, the method disclosed in the present invention does not use them simultaneously as in case of Kalman filter implementation. At any given point of time SOC is estimated using either Direct or Indirect Method. The direct method and indirect method are called upon based on a strategy so that their merits are exploited and demerits are mitigated.

The indirect method is called whenever:

1. Magnitude of current is small (less than a threshold)

2. Battery has reached steady (or static) condition (or Relaxed)

Due to above conditions, a simple resistance model in place of AC impedance can be afforded. Because of small current, errors in the estimation of Z (or R) have less effect on OCV estimation as per Eq. 3.

The direct method is called whenever:

1. SOC was estimated in the previous sample time and

2. The battery current magnitude is above a threshold value i.e. TH_3. or

3. The battery is in transient state i.e. it is yet to be relaxed.

The smaller the value of TH_3, less is the error in SOC estimation using indirect method. However, smaller threshold prolongs Coulomb counting hence error is higher due to divergence in Coulomb counting. For small resistance R, higher TH_3 is chosen, which is temperature dependent. For low temperatures resistance is higher, therefore TH_3 is smaller.

The battery is allowed to relax since the battery terminal voltage is not equal to its expected value (OCV+IR). The relaxation time is temperature dependent e.g. for low temperatures the setting time is very high and hence the value of the threshold increases.

Estimation of R:

According to the equation 3, know Z (or R), V_{b} and I_{b} has to be known in order to find OCV. Since indirect method is used during steady state situation only, AC impendence Z is replaced by resistance R.

The equation 3 is rewritten in time domain in discretized form as below:

OCV(n)=V_{b}(n)−I_{b}(n)R Eq. 4

The equation for online estimation of battery resistance R is derived from Eq. 4 as below:

OCV(n−1)=V_{b}(n−1)−I_{b}(n−1)R(n−1)

The equation is for (n−1)^{th} sample

And,

OCV(n)=V_{b}(n)−I_{b}(n)R(n)

The equation is for n^{th} sample.

It is assumed that OCV and R are slow varying parameters, therefore they are treated to be constant during (n−1)^{th} and the next n^{th} sample time. Then the above two equations are re-written as:

OCV=V_{b}(n−1)−I_{b}(n−1)R

And,

OCV=V_{b}(n)−I_{b}(n)R.

Hence the resistance is calculated by following formula.

$$R = \frac{{V}_{b} ( n ) - {V}_{b} ( n - 1 )}{{I}_{b} ( n ) - {I}_{b} ( n - 1 )} .$$

Since there exists a measurement noise, R is estimated only when the denominator is reasonably large, say greater than. TH_1. This threshold is sufficiently larger e.g. 5 times minimum than current sensor precision, in addition to the noise which is 0.25 A. If the threshold is selected to be too high then rate of update of R reduces. It is found that the optimum value of TH_1=2 A for all temperatures.

Also, OCV is assumed to be nearly constant during (n−1)^{th} and n^{th} samples which is possible only when SOC is nearly constant. SOC remains nearly constant only when I_{b} is smaller than a threshold i.e. TH_2. It is noted that too small a value of TH_2 reduces the update rate of R. Therefore R is estimated whenever abs[I_{b}(n)−I_{b}(n−1)] is greater than TH_2 and either I_{b}(n−1) or I_{b}(n) is less than a threshold TH_2. The estimated value of R is used for estimation of OCV from V_{b} and I_{b} until the next update of R.

Steps to Determine SOC:

Step 1: System initiation is done. After key on, various states stored in EEPROM just before the key-off are read. For example, previously computed battery capacity ‘C’, DC current offset ‘d’, differential SOC (Aₖ) and charge transfer (Bₖ) values are read at this instant. Least Mean Square (LMS) points are used for estimating battery capacity and SOH computation.

Step 2: The values of voltage, current and temperature ADC samples sampled at instant n i.e. v[n], i[n], T[n] are retrieved.

Step 3: If sample at an instant n is not the first sample after key on, then difference between battery current, measured at consecutive instants, is found to be significant i.e. the magnitude of this difference is greater than a TH_1 and also the average of battery current measured is smaller than a threshold TH_2, then resistance ‘R’ is updated. Once R is updated then the same value is used in indirect method until the next update of R.

The threshold TH_1 is based on resolution and accuracy of current measurement. Generally, it is 5 to 8 times more than the current measurement resolution so that inaccuracy of estimation of resistance due to error/noise in current measurement is minimized. However, high value of TH_1 reduces the update rate of R which is essentially a non constant parameter which depends upon temperature, SOC and SOH. The formula used for calculating R is derived under the assumption that the change is SOC, and hence OCV, between consecutive instants is negligible. This assumption is true only when the average of battery current is smaller than TH_2. Thus TH_2 is also dependent on battery capacity. Higher the battery capacity lower is the change in SOC for the same current from one instant to another. Hence TH_2 is proportional to battery capacity. The smaller TH_2 improves accuracy of estimation of R but reduces the update rate of time varying battery resistance R.

Step 4: If previous battery SOC is available before instant ‘n’, and if magnitude of battery current is greater than a threshold TH_3, then SOC at the present instant ‘n’ is computed according to Equation 2, which is a direct method equation, where ΔT is 1 second. Also Relaxation counter is set to an integer number that corresponds to the relaxation time based on temperature and current magnitude i[n].

The computation of SOC at this step is a direct method.

Step 5: If magnitude of battery current is less than the threshold TH_3 and the relaxation counter is greater than zero, then relaxation counter is decremented by integer 1 and then SOC is computed by Equation 2, where ΔT is 1 second. A nonzero relaxation counter indicates that battery is not sufficiently rested or not reached steady state.

Otherwise, if battery current is less than a threshold TH_4 and relaxation counter is zero, then SOC is found out from terminal voltage v[n] at the instant ‘n’, assuming that it is OCV. This is indirect method.

Otherwise, if magnitude of battery current is less than the threshold TH_3, relaxation counter is zero and resistance value is available, then OCV is computed using equation OCV=V[n]−R*i[n]. Hence the corresponding SOC value is found out.

It is noted that high TH_3 reduces the number of estimations by direct method while it makes computation of SOC by indirect method prone to modeling errors and parameter estimation errors. On the other hand, small TH_3 increases dependency on direct method and reduces inaccuracy of SOC in indirect method. Since direct method diverges if done continuously, small TH_3 is recommended only when current measurement accuracy is high. In case, if current measurement has less resolution or accuracy, it is advantageous to increase TH_3. While selecting or tuning TH_3, drive profiles and probability density curve of battery charging and discharging currents is also considered.

Also it is noted that the selection of TH_4 depends on the resolution of current measurement and also on battery capacity. This threshold is 1.5 times the current measurement resolution or 1/30 of the battery capacity.

Step 6: SOH is estimated to update capacity whenever battery capacity is computed.

Step 7: Repeat Steps from 2 to 7 for every new measurement sample.

Estimation of Battery Capacity & SOH:

SOH, generally stated in percentage, is the ratio of actual battery capacity to the rated or fresh battery capacity. This parameter indicates health of the battery. Typically, a battery is allowed to work in a vehicle till it reaches 70% of its rated capacity (i.e. 80% SOH). The battery has to be replaced if the health falls below 70%.

The estimation of SOH follows estimation of present battery capacity which is computed from the knowledge of change is SOC and the charge transfer.

Battery capacity and SOH is estimated using SOC obtained by indirect method. In equation 2, actual battery capacity C is not known. The SOC values are determined by way of the method described for SOC estimation. There is also unknown current sensor DC offset which can not be neglected.

$$C = \frac{{\sum }_{k = n 1}^{n 2} i ( k ) Δ T}{SOC ( n 2 ) - SOC ( n 1 )}$$

In the above equation, unknown current sensor DC offset even if very small cannot be neglected as it gets accumulated during summation at the numerator. The above equation is rewritten assuming the current measurement DC offset to be equal to ‘d’.

$$C = \frac{{\sum }_{k = n 1}^{n 2} ( i ( k ) - d ) Δ T}{SOC ( n 2 ) - SOC ( n 1 )}$$

The numerator is simply charge transfer in Coulombs between n1 and n2. This numerator is indicated by y. Denominator is change in SOC or differential SOC between n1 and n2 due to charge transfer and is depicted by x.

The sampling is done per unit time i.e ΔT=1 for the sake of simplicity. Then the above equation is rearranged as the following.

$$C * [ SOC ( n 2 ) - SOC ( n 1 ) ] + d = {\sum }_{k = n 1}^{n 2} i ( k )$$

$$O r$$

$$C * A + d = B$$

Where A is SOC difference and B is accumulation of measured current i.e. measured charge transfer.

The unknowns are C and d.

Due to errors in estimation of SOC, the term A will be erroneous. It can introduce large error in the estimation of C particularly when there is a large difference between estimated differential and expected differential SOC. It is therefore important that the magnitude of A is reasonably large. Hence, a condition is imposed so that the magnitude of the SOC difference (i.e. A) should be greater than a threshold (TH_5) to estimate C. Higher this threshold, better is the accuracy but update rate of capacity estimation reduces drastically. For example, for HEV applications the value of this threshold should not be greater than 15 when the battery is operated within a small range of SOC e.g. 60 to 40. The optimum value of TH_5 is found to be within 10 to 15 for HEV and within 15 to 20 for EV applications.

Since C is expected to be constant for fairly long duration (several months), several values of x and y are collected such that abs(x)>TH_5. Indexing A and B as Aᵢ and Bᵢ and from Eq. 5,

$$\begin{matrix}\begin{matrix}\begin{matrix}\begin{matrix}{CA}_{1} + d = {B}_{1} \\ {CA}_{2} + d = {B}_{2}\end{matrix} \\ {CA}_{3} + d = {B}_{3}\end{matrix} \\ …\end{matrix} \\ {CA}_{n} + d = {B}_{n}\end{matrix}$$

The above determined set of n equations with two unknowns C and d are solved using Least Mean Square method.

X=[(A1,1), (A2,1), . . . (An,1)]^{T} is n×2 matrix.

Y=[B1, B2, . . . , Bn]^{T} is n×1 matrix.

$${[ C , d ]}^{T} = {( {X}^{T} X )}^{- 1} {X}^{T} Y$$

$$SOH = 100 \frac{C}{{C}_{n}} .$$

To compute X, only indirect method (Type-1) is used. This is because SOC by direct method requires the knowledge of actual battery capacity C.

Steps to Determine SOH:

Step 1: The estimated SOC[n1], SOC[n2], SOC[n3], SOC[n m+1] for m=20 at sample times n1, n2, n3 . . . , nm are tapped such that magnitude of difference between consecutive SOCs is greater than the threshold TH_5. SOHk is estimated using Indirect Method. Also the accumulated current or charge transfer Bk that occurred between nk and n(k+1) samples is computed.

Step 2: If A is the difference between two consecutive SOCs such that A1=SOC[n2]−SOC[n1], A2=SOC[n3]−SOC[n4] . . . Am=SOC[n(m+1)]−SOC[nm]

The following matrix is constructed:

X=[(A1,1), (A2,1), . . . (An,1)]^{T} is n×2 matrix.

Y=[B1, B2, . . . , Bn]^{T} is n×1 matrix.

[C,d]^{T}=(X^{T}X)⁻¹X^{T}Y
C is the battery capacity and d is the DC current measurement offset.

$$SOH = 100 \frac{C}{{C}_{n}}$$

Accordingly, the present invention describes a method and system to minimize DC offset current and battery capacitance errors thereby compensating for modeling errors and parameter estimation errors during determination of accurate State of Charge (SOC) of a battery, comprising a direct method and an indirect method, wherein said direct method and an indirect method are not used simultaneously, are used alternatively or conditionally depending on battery current status; after initiation of the system, determination of State of Health (SOH) of the battery and determination of battery capacity using least square method.

Also, the method and system to minimize DC offset current and battery capacitance errors during determination of SOC comprises invoking a direct method at an instant ‘n’, where the battery, is in a transient state, or when the magnitude of battery current is greater than a predetermined threshold value TH_3, and a relaxation counter is decremented by an integer value from the set value.

Further, the method and system to minimize DC offset current and battery capacitance errors during determination of SOC comprises invoking an indirect method at an instant ‘n’, where the battery is sufficiently relaxed and the magnitude of battery current is less than a predetermined threshold value TH_4.

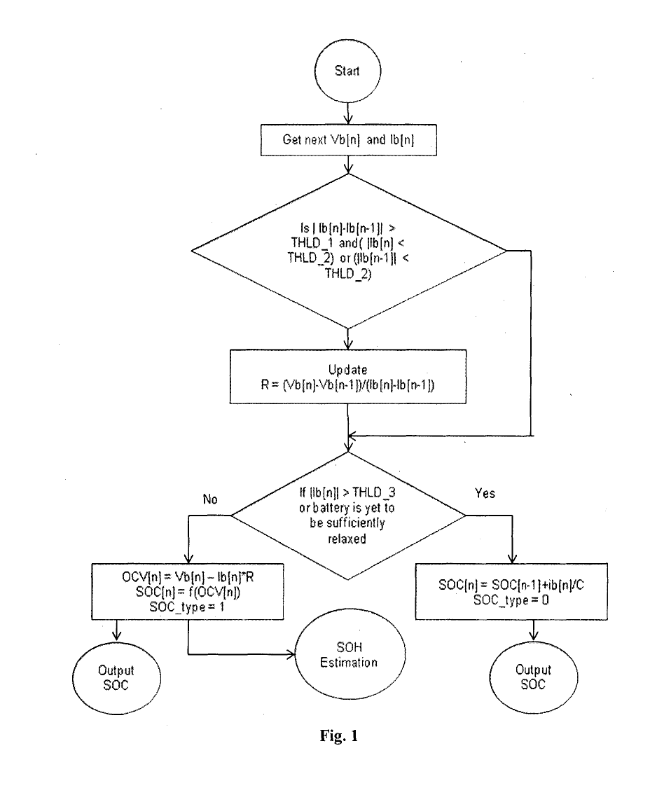

As illustrated in FIG. 1, the method and system initially determines the battery capacity and SOH of battery after initiation of the system using least square method; then variables i.e. voltage, current and temperature at any instant ‘n’ are sampled; value of resistance ‘R’ at any instant ‘n’ is determined, where the magnitude of the battery current is greater than a threshold value TH_1, or where the magnitude of the battery current is less than a threshold value TH_2; SOC at any instant ‘n’ by a direct method is determined where the battery is yet to be sufficiently relaxed, the magnitude of battery current is greater than a threshold value TH_3; alternately SOC at any instant ‘n’ by a direct method determined where the magnitude of battery current is less than said threshold value TH_3 and the relaxation counter is decremented by an integer value from the set value; or SOC is determined by an indirect method where battery is sufficiently relaxed & the magnitude of battery current is less than a threshold value TH_4; battery capacity ‘C’ is calculated using estimated SOC by Least Mean Square Method; state of health (SOH) of battery is determined on computing SOC with minimized DC offset current and battery capacitance. The described steps are repeated for measuring SOC new variables, where the direct method and indirect method are not used at the same time but are used alternatively or determined by battery current status, for eliminating or minimizing DC offset current and unknown battery capacitance.

The SOC of a battery is further determined by a direct method where the magnitude of battery current is greater than a threshold value TH_3 and the battery is yet to be sufficiently relaxed to set the relaxation counter. The method consists of determining initially the battery capacity and SOH of battery after initiation of the system using least square method; sampling the variables i.e. voltage, current and temperature at any instant ‘n’; determining SOC at previous instant ‘n−1’; sampling of battery current at variable sampling period (ΔT) between ‘n−1’ & ‘n’; and measuring exact battery capacity ‘C’ and DC offset current ‘d’.

SOC of a battery is further determined by a direct method where the magnitude of battery current is less than said threshold value TH_3 and the relaxation counter is decremented from said set value. The method consists of determining initially the battery capacity and SOH of battery after initiation of the system using least square method; sampling the variables i.e. voltage, current and temperature at any instant ‘n’; determining the value of resistance ‘R’ at any instant ‘n’, where the magnitude of the battery current is greater than a threshold value TH_1, or where the magnitude of the battery current is less than a threshold value TH_2; determining SOC at previous instant ‘n−1’; sampling of battery current at variable sampling period (ΔT) between ‘n−1’ and ‘n’; measuring of exact battery capacity ‘C’ and DC offset current ‘d’.

The SOC of a battery is alternately determined by an indirect method, where battery is sufficiently relaxed, the magnitude of battery current is less than a threshold value TH_4. The method includes determining initially the battery capacity and SOH of battery after initiation of the system using least square method; sampling the variables i.e. voltage, current and temperature at any instant ‘n’; determining Open Circuit voltage (OCV) of a battery by measuring battery terminal voltage (V_{b}), battery current (I_{b}) and resistive AC impedance (Z); estimating battery SOC by graphical method.

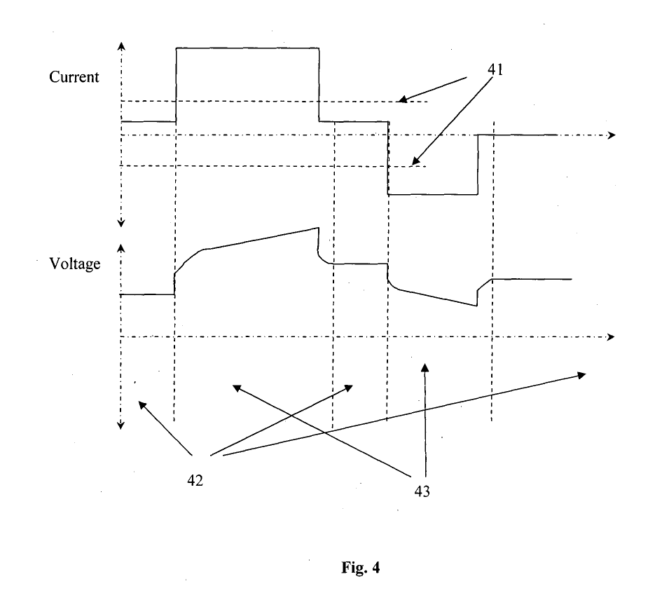

FIG. 4 illustrates the battery current status directed to the use of direct and indirect methods. The magnitude of difference between SOCs should be higher than a threshold TH_5 (41) in order to calculate battery capacity. Region of Indirect Method(42) is a region of Low current and steady state and Region of Direct Method(43) is a region of High current and transient state.

In the disclosed method and system, the resistance ‘R’ is determined when the magnitude of the difference between battery currents i.e. abs[I_{b}(n)−I_{b}(n−1)] is greater than a threshold value i.e. TH_1. The resistance ‘R’ is also determined when either battery current of previous state i.e. I_{b}(n−1) or running state i.e. I_{b}(n) is less than a threshold i.e. TH_2.

When the battery is yet to be sufficiently relaxed, the relaxation counter is set to an integer number corresponding to the relaxation time based on temperature and magnitude of battery current. The relaxation counter is further reduced by factor one when magnitude of battery current is less than said threshold value TH_3.

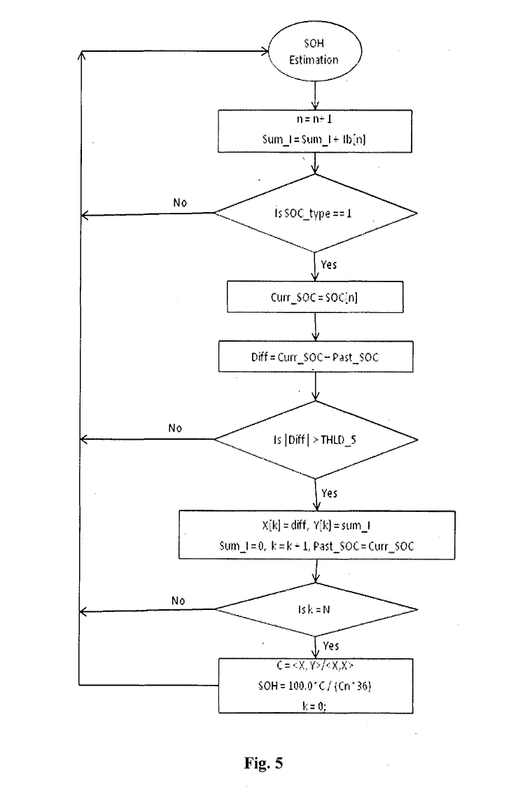

As illustrated in FIG. 5, the method and system to determine said SOH consists of tapping the estimated SOC by the indirect method at various instants, where magnitude of difference (Ak) between two consecutive SOCs is greater than a threshold value TH_5; computing the accumulated current or charge transfer Bk between two consecutive samples; calculating battery capacity ‘C’ using parameters estimated by Least Mean Square Method; calculating SOH using the battery capacity ‘C’. The battery in the present invention can be a lithium based battery.

The method and system of the invention maybe utilized to determine SOC for various types of batteries and various applications. SOC maybe determined for batteries used in various applications, like hybrid vehicle battery, electric vehicle battery, an inverter battery, etc. Additionally, the battery SOC maybe determined either online, while the battery is in use or offline, while the battery is resting. The above examples, will serve to illustrate the practice of this invention being understood that the particular shown by way of example, for purpose of illustrative discussion of preferred embodiment of the invention and are not limiting the scope of the invention.

1-14. (canceled)

15. A method comprising:
determining a SOC of a battery using a direct method during a first set of one or more conditions of a battery current of the battery;
determining the SOC of the battery using an indirect method during a second set of one or more conditions of the battery current of the battery, wherein the second set of one or more conditions of the battery current is different than the first set of one or more conditions of the battery current, and wherein the direct method and the indirect method are not used simultaneously; and
after initiation of a system associated with the battery, determining a State of Health (SOH) of the battery and a capacity of the battery using a least square method.

16. The method of claim 15, wherein the direct method is utilized to determine the SOC during at least one of the following conditions:
the battery is in a transient state; or
a magnitude of the battery current is greater than a predetermined threshold value TH_3 and a relaxation counter is decremented by an integer value from a set value.

17. The method of claim 16, wherein the indirect method is utilized to determine the SOC when the battery is sufficiently relaxed and the magnitude of the battery current is less than a predetermined threshold value TH_4.

18. The method of claim 15, further comprising:
(a) initially determining the capacity and SOH of the battery periodically using the least square method with help of the SOC estimated using the indirect method;
(b) sampling the current, a voltage, and a temperature of the battery at an instant ‘n’;
(c) determining a value of a resistance at the instant ‘n’ when a change in magnitude of the battery current is greater than a predetermined threshold value TH_1 and the magnitude of the battery current is less than a predetermined threshold value TH_2;
(d) determining the SOC at the instant ‘n’ using:
the direct method when the battery is yet to be sufficiently relaxed and the magnitude of the battery current is greater than a predetermined threshold value TH_3;
the direct method when the magnitude of the battery is less than the predetermined threshold value TH_3 and a relaxation counter is decremented by an integer value from a set value; or
the indirect method when the battery is sufficiently relaxed and the magnitude of the battery current is less than a predetermined threshold value TH_4;
(e) calculating the capacity of the battery using the SOC by a least mean square method;
(f) determining the SOH of the battery using the determined SOC; and
(g) repeating steps ‘b’ to ‘f’ and measuring one or more new variables relating to the SOC.

19. The method of claim 15, wherein a magnitude of the battery current is greater than a predetermined threshold value TH_3 and the battery is yet to be sufficiently relaxed to set a relaxation counter, and wherein determining the SOC using the direct method comprises:
(a) determining the capacity and the SOH of the battery periodically using the least square method and updating the capacity and a DC offset value in a formula used in the direct method;
(b) sampling the current, a voltage, and a temperature of the battery at an instant ‘n’;
(c) determining the SOC at a previous instant ‘n−1’;
(d) sampling the battery current at a variable sampling period between ‘n−1’ and ‘n’; and
(e) measuring the capacity and DC offset value.

20. The method of claim 15, wherein a magnitude of the battery current is greater than a predetermined threshold value TH_3 and a relaxation counter is decremented from a set value, and wherein determining the SOC using the direct method comprises:
(a) determining the capacity and the SOH of the battery periodically using the least square method;
(b) sampling the current, a voltage, and a temperature of the battery at an instant ‘n’;
(c) determining a value of a resistance at the instant ‘n’ when a magnitude of the battery current is greater than a second threshold or is less than a third threshold;
(d) determining the SOC at a previous instant ‘n−1’;
(e) sampling the battery current at a variable sampling period between ‘n−1’ and ‘n’; and
(f) measuring the capacity and DC offset value.

21. The method of claim 15, wherein the battery is sufficiently relaxed and the magnitude of the battery current is less than a predetermined threshold value TH_4, and wherein determining the SOC using the indirect method comprises:
(a) determining the capacity and the SOH of the battery periodically using the least square method;
(b) sampling the current, a voltage, and a temperature of the battery at an instant ‘n’;
(c) determining an Open Circuit Voltage (OCV) of the battery by measuring the battery current, a battery terminal voltage, and a resistive impedance; and
(d) estimating the SOC by a graphical method.

22. The method of claim 15, further comprising determining a resistance when a magnitude of a change in battery current between an instant ‘n’ and a previous instant ‘n−1’ is greater than a threshold value.

23. The method of claim 15, further comprising determining a resistance when either the battery current at an instant ‘n’ or the battery current at a previous instant ‘n−1’ is less than a threshold value.

24. The method of claim 15, further comprising determining the battery to not be sufficiently relaxed to set a relaxation counter to an integer number corresponding to a relaxation time based on a temperature of the battery and a magnitude of the battery current.

25. The method of claim 15, further comprising reducing a relaxation counter by a factor of one when a magnitude of the battery current is less than a predetermined threshold value TH_3.

26. The method of claim 15, wherein determining the SOH comprises:
(a) sampling the SOC by the indirect method at various instants, wherein a magnitude of a difference between two consecutive SOCs is greater than a predetermined threshold value TH_5;
(b) computing an accumulated current or charge transfer between two consecutive samples;
(c) calculating the capacity using one or more parameters estimated in steps ‘a’ and ‘b’ by a least mean square method; and
(d) calculating the SOH using the capacity calculated in step ‘c’.

27. The method of claim 26, wherein the capacity is determined when the magnitude of the difference between the two consecutive SOCs is greater than the predetermined threshold value TH_5.

28. The method of claim 15, wherein the battery is a Lithium-based battery.

29. A system comprising:
a processor configured to:
determine a State of Charge (SOC) of a battery using a direct method during a first set of one or more conditions of a battery current of the battery;
determine the SOC of the battery using an indirect method during a second set of one or more conditions of a current of the battery, wherein the second set of one or more conditions of the current is different than the first set of one or more conditions of the battery current, and wherein the direct method and the indirect method are not used simultaneously; and
determine a State of Health (SOH) of the battery and a capacity of the battery using a least square method.

30. The system of claim 29, wherein the direct method is utilized to determine the SOC during at least one of the following conditions:
the battery is in a transient state; or
a magnitude of the battery current is greater than a predetermined threshold value TH_3 and a relaxation counter is decremented by an integer value from a set value.

31. The system of claim 30, wherein the indirect method is utilized to determine the SOC when the battery is sufficiently relaxed and the magnitude of the battery current is less than a predetermined threshold value TH_4.

32. The system of claim 29, wherein the processor is configured to:
(a) initially determine the capacity and SOH of the battery periodically using the least square method with help of the SOC estimated using the indirect method;
(b) sample the current, a voltage, and a temperature of the battery at an instant ‘n’;
(c) determine a value of a resistance at the instant ‘n’ when a change in magnitude of the battery current is greater than a predetermined threshold value TH_1 and the magnitude of the battery current is less than a predetermined threshold value TH_2;
(d) determine the SOC at the instant ‘n’ using:
the direct method when the battery is yet to be sufficiently relaxed and the magnitude of the battery current is greater than a predetermined threshold value TH_3;
the direct method when the magnitude of the battery is less than the predetermined threshold value TH_3 and a relaxation counter is decremented by an integer value from a set value; or
the indirect method when the battery is sufficiently relaxed and the magnitude of the battery current is less than a predetermined threshold value TH_4;
(e) calculate the capacity of the battery using the SOC by a least mean square method;
(f) determine the SOH of the battery using the determined SOC; and
(g) repeat steps ‘b’ to ‘f’ and measuring one or more new variables relating to the SOC.

33. The system of claim 29, wherein a magnitude of the battery current is greater than a predetermined threshold value TH_3 and the battery is yet to be sufficiently relaxed to set a relaxation counter, and wherein the processor is configured to determine the SOC using the direct method by:
(a) determining the capacity and the SOH of the battery periodically using the least square method and updating the capacity and a DC offset value in a formula used in the direct method;
(b) sampling the current, a voltage, and a temperature of the battery at an instant ‘n’;
(c) determining the SOC at a previous instant ‘n−1’;
(d) sampling the battery current at a variable sampling period between ‘n−1’ and ‘n’; and
(e) measuring the capacity and DC offset value.

34. The system of claim 29, wherein a magnitude of the battery current is greater than a predetermined threshold value TH_3 and a relaxation counter is decremented from a set value, and wherein the processor is configured to determine the SOC using the direct method by:
(a) determining the capacity and the SOH of the battery periodically using the least square method;
(b) sampling the current, a voltage, and a temperature of the battery at an instant ‘n’;
(c) determining a value of a resistance at the instant ‘n’ when a magnitude of the battery current is greater than a second threshold or is less than a third threshold;
(d) determining the SOC at a previous instant ‘n−1’;
(e) sampling the battery current at a variable sampling period between ‘n−1’ and ‘n’; and
(f) measuring the capacity and DC offset value.

35. The system of claim 29, wherein the battery is sufficiently relaxed and the magnitude of the battery current is less than a predetermined threshold value TH_4, and wherein the processor is configured to determine the SOC using the indirect method by:
(a) determining the capacity and the SOH of the battery periodically using the least square method;
(b) sampling the current, a voltage, and a temperature of the battery at an instant ‘n’;
(c) determining an Open Circuit Voltage (OCV) of the battery by measuring the battery current, a battery terminal voltage, and a resistive impedance; and
(d) estimating the SOC by a graphical method.
